(19) United States
(12) Patent Application Publication
(10) Pub. No.: US 2014/0149812 A1
(43) Pub. Date: May 29, 2014

(54) SCAN TEST CIRCUITRY WITH CONTROL CIRCUITRY CONFIGURED TO SUPPORT A DEBUG MODE OF OPERATION

(71) Applicant: LSI CORPORATION, Milpitas, CA (US)

(72) Inventors: Ramesh C. Tekumalla, Breinigsville, PA (US); Vijay Sharma, Pune (IN)

(73) Assignee: LSI Corporation, Milpitas, CA (US)

(21) Appl. No.: 13/685,875

(22) Filed: Nov. 27, 2012

(51) Int. Cl. G01R 31/317; G01R 31/3177

(52) U.S. Cl. CPC G01R 31/31705; G01R 31/3177
USPC 714/727

(57) ABSTRACT

An integrated circuit comprises scan test circuitry and additional circuitry subject to testing utilizing the scan test circuitry. The scan test circuitry comprises a plurality of scan chains each having a plurality of scan cells. The scan test circuitry further comprises control circuitry comprising first switching elements configured to control selective application of respective scan input signals to respective scan inputs of respective ones of the plurality of scan chains and second switching elements configured to control selective application of a shift enable signal to respective shift enable inputs of the respective ones of the plurality of scan chains. By appropriate control of the switching elements using test data register bits or other scan chain specific control signals, one or more debug modes can be supported by the scan test circuitry of the integrated circuit.

### BACKGROUND

Integrated circuits are often designed to incorporate scan test circuitry that facilitates testing for various internal fault conditions. Such scan test circuitry typically comprises scan chains comprising multiple scan cells. The scan cells may be implemented, by way of example, utilizing respective flip-flops. The scan cells of a given scan chain are configurable to form a serial shift register for applying test patterns at inputs to combinational logic of the integrated circuit. The scan cells of the given scan chain are also used to capture outputs from other combinational logic of the integrated circuit.

Scan testing of an integrated circuit may therefore be viewed as being performed in two repeating phases, namely, a scan shift phase in which the flip-flops of the scan chain are configured as a serial shift register for shifting in and shifting out of test patterns, and a scan capture phase in which the flip-flops of the scan chain capture combinational logic outputs. These two repeating scan test phases may be collectively referred to herein as a scan test mode of operation of the integrated circuit, or as simply a scan mode of operation. Outside of the scan test mode and its scan shift and scan capture phases, the integrated circuit may be said to be in a functional mode of operation. Other definitions of the scan test and functional operating modes may also be used.

As integrated circuits have become increasingly complex, scan compression techniques have been developed which reduce the number of test patterns that need to be applied when testing a given integrated circuit, and therefore also reduce the required test time. Additional details regarding compressed scan testing are disclosed in U.S. Pat. No. 7,831,876, entitled “Testing a Circuit with Compressed Scan Subsets,” which is commonly assigned herewith and incorporated by reference herein.

Despite the performance advantages associated with scan compression, there nonetheless remains a need for further improvements in scan test circuitry. For example, conventional scan test circuitry can be particularly difficult to debug for compression faults, since the scan chain contents are not directly observable when using scan compression. More particularly, in a typical conventional arrangement, the scan chain inputs are driven by respective outputs of a decompressor and the scan chain outputs are supplied as respective inputs to a compressor. Compressed test patterns from a test pattern generator are decompressed by the decompressor for application to the scan chains, and the corresponding results provided at the scan chain outputs are compressed by the compressor. As a result, the compressed test data observed at the output of the compressor is a function of groups of scan cells from multiple chains rather than a function of scan cells from a single chain. This causes a loss of mapping between observed test data and scan cells, leading to reduced diagnostic resolution. Accordingly, conventional techniques cannot readily determine which scan cell or cells of a particular scan chain may have contributed to a given test pattern failure.

### SUMMARY

In one embodiment, an integrated circuit comprises scan test circuitry and additional circuitry subject to testing utilizing the scan test circuitry. The scan test circuitry comprises a plurality of scan chains each having a plurality of scan cells. The scan test circuitry further comprises control circuitry comprising first switching elements configured to control selective application of respective scan input signals to respective scan inputs of respective ones of the plurality of scan chains and second switching elements configured to control selective application of a shift enable signal to shift enable inputs of the respective ones of the plurality of scan chains.

By appropriate control of the switching elements using test data register bits or other types of control signals, a compression debug mode of operation is supported by the scan test circuitry of the integrated circuit.

For example, in such a compression debug mode, a first subset of the scan chains have the corresponding scan input signals applied to their scan inputs and have the shift enable signal applied to their shift enable inputs, and a second subset of the scan chains have a first predetermined signal value at a first logic level applied to their scan inputs and a second predetermined signal value at a second logic level applied to their shift enable inputs. This allows constant values to be shifted through particular selected scan chains while the other scan chains continue to operate in their normal scan testing configuration, thereby facilitating debug of compression faults. Diagnostic resolution is considerably improved, permitting straightforward identification of one or more scan cells that have contributed to a given test pattern failure. For example, contents of individual scan chains can be readily isolated and observed at the output of a compressor.

Although some embodiments are particularly well suited for use with compressed scan testing, other embodiments of the invention do not require utilization of compressed scan testing. Accordingly, control circuitry of the type disclosed herein can be adapted for use in providing a variety of different types of debug modes of operation, including one or more debug modes in test environments that utilize noncompressed scan testing.

### BRIEF DESCRIPTION OF THE DRAWINGS

FIG. 1 is a block diagram showing an integrated circuit testing system comprising a tester and an integrated circuit under test in one embodiment.

FIG. 2 shows a more detailed view of a portion of the integrated circuit in the testing system of FIG. 1.

FIGS. 3 through 6 show control circuitry associated with a compression debug mode of operation in illustrative embodiments.

FIG. 7 shows one possible implementation of the testing system of FIG. 1.

FIG. 8 is a block diagram of a processing system for generating an integrated circuit design comprising control circuitry of the type illustrated in FIGS. 3 through 6.

### DETAILED DESCRIPTION

Embodiments of the invention will be illustrated herein in conjunction with exemplary testing systems and corresponding integrated circuits comprising scan test circuitry for supporting scan testing of additional circuitry of those integrated circuits. It should be understood, however, that embodiments of the invention are more generally applicable to any testing system or associated integrated circuit in which it is desirable to provide improved diagnostic resolution of scan chains of scan test circuitry in one or more debug modes of operation.

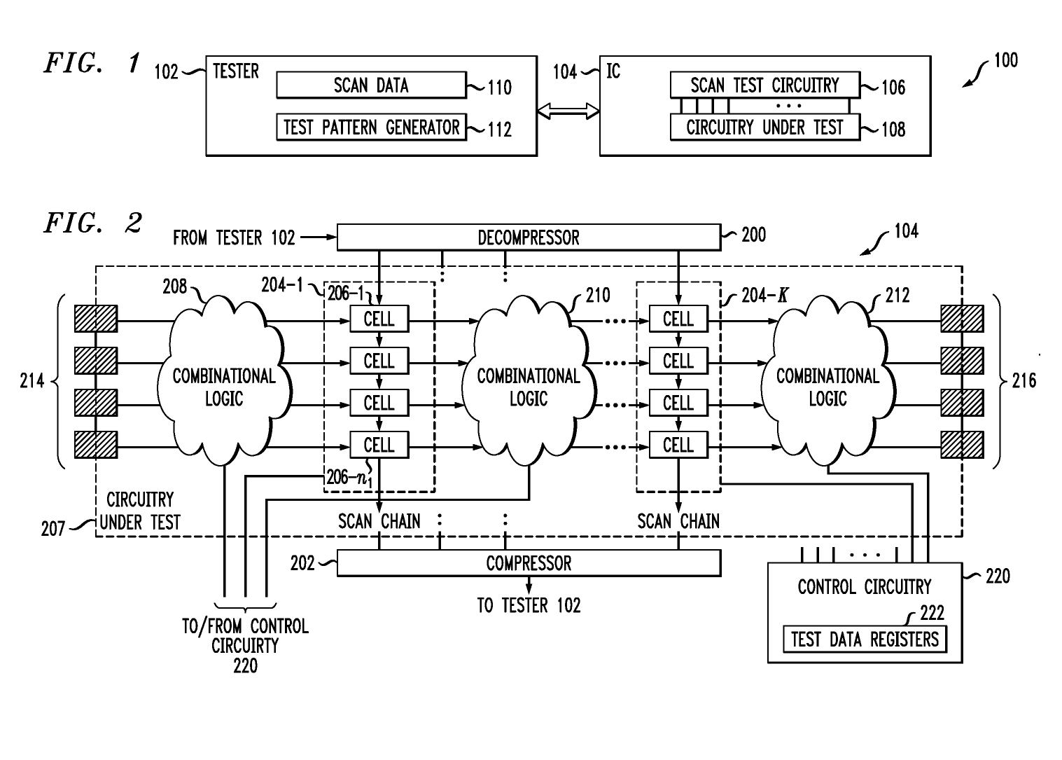

FIG. 1 shows an embodiment of the invention in which a testing system 100 comprises a tester 102 and an integrated circuit under test 104. The integrated circuit 104 comprises scan test circuitry 106 coupled to additional internal circuitry 108 that is subject to testing utilizing the scan test circuitry 106. The tester 102 stores scan data 110 associated with scan testing of the integrated circuit. Such scan data may correspond to test patterns provided by a test pattern generator 112. In other embodiments, at least a portion of the tester 102, such as the test pattern generator 112, may be incorporated into the integrated circuit 104. Alternatively, the entire tester 102 may be incorporated into the integrated circuit 104, as in a built-in self-test (BIST) arrangement.

The test pattern generator 112 may be implemented as an automatic test pattern generator (ATPG), and may be viewed as an example of what is more generally referred to herein as a test generation tool. Such a test generation tool may be part of automated test equipment (ATE) comprising the tester 102.

The particular configuration of testing system 100 as shown in FIG. 1 is exemplary only, and the testing system 100 in other embodiments may include other elements in addition to or in place of those specifically shown, including one or more elements of a type commonly found in a conventional implementation of such a system. For example, various elements of the tester 102 or other parts of the system 100 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

The integrated circuit 104 may be configured for installation on a circuit board or other mounting structure in a computer, server, mobile telephone or other type of communication device. Such communication devices may also be viewed as examples of what are more generally referred to herein as “processing devices.” The latter term is also intended to encompass storage devices, as well as other types of devices comprising data processing circuitry.

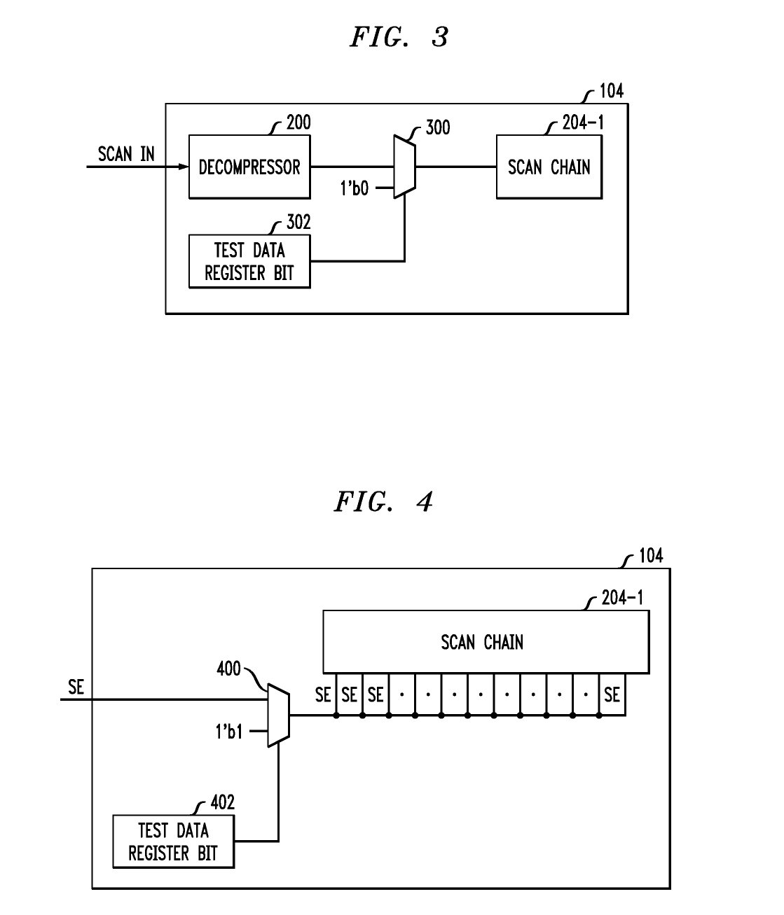

Embodiments of the present invention are may be configured to utilize compressed or noncompressed scan testing, and embodiments of the invention are not limited in this regard. However, the embodiments shown in FIGS. 2 through 6 will be described primarily in the context of compressed scan testing.

Referring now to FIG. 2, portions of one potential configuration of the integrated circuit 104 are shown in greater detail. In this compressed scan testing arrangement, the scan test circuitry 106 comprises a decompressor 200, a compressor 202, and a plurality of scan chains 204-k, where k=1, 2, . . . K.

Each of the scan chains 204 comprises a plurality of scan cells 206. A scan shift control signal is utilized to cause the scan cells 206 of at least a given one of the scan chains 204 to form a serial shift register during scan testing. The scan shift control signal may comprise, for example, a scan enable (SE) signal, such that the scan cells of the given scan chain form the serial shift register responsive to the SE signal being at a first designated logic level (e.g., a logic “1” level) and the scan cells capture functional data when the SE signal is at a second designated logic level (e.g., a logic “0” level). A single SE signal may be used to control all of the scan chains 204, or only a subset of those scan chains, with the remaining scan chains being controlled using one or more other SE signals.

The SE signal in the present embodiment basically controls configuration of scan cells of a scan chain to form a serial shift register for shifting in and shifting out of test patterns. The SE signal may therefore be considered a type of scan shift enable signal, or more generally, a type of scan shift control signal. All such signals are still more generally referred to herein as “shift enable” signals. Accordingly, the abbreviation SE herein may be viewed as denoting scan enable or more generally shift enable.

When the scan chains 204 are configured to form respective serial shift registers for shifting in and shifting out scan test data associated with one or more test patterns to be applied by the tester 102, the scan test circuitry may be said to be in a scan shift phase of a scan test mode of operation. It should be appreciated, however, that a wide variety of other types of scan shift control signals and sets of integrated circuit operating modes and phases may be used in other embodiments. These embodiments therefore do not require the use of any particular definition of operating modes and phases.

The scan chains 204 may be associated with multiple distinct clock domains, or a single clock domain. It will be assumed in some embodiments that at least one of the scan chains 204 is a multiple clock domain scan chain, that is, a scan chain comprising sub-chains associated with respective distinct clock domains. Such sub-chains of a multiple clock domain scan chain may be separated from one another by lockup latches. Also, one or more of the sub-chains may be selectively bypassed using clock domain bypass circuitry so as to not be part of the serial shift register formed by the scan chain in the scan shift phase. For example, such clock domain bypass circuitry may be configured to bypass one or more of the sub-chains that are determined to be inactive for a particular test pattern, and the clock domain bypass circuitry may bypass different ones of the sub-chains for different test patterns. Additional details regarding clock domain bypass circuitry that may be utilized in embodiments of the invention may be found in U.S. patent application Ser. No. 13/280,797, filed Oct. 25, 2011 and entitled “Dynamic Clock Domain Bypass for Scan Chains,” which is commonly assigned herewith and incorporated by reference herein.

The scan chains 204 are generally arranged in parallel with one another between respective outputs of the decompressor 200 and respective inputs of the compressor 202, such that in the scan shift mode of operation, scan test input data from the decompressor 200 is shifted into the scan chains 204 and scan test output data is shifted out of the scan chains 204 into the compressor 202.

The first scan chain 204-1 is of length n₁ and therefore comprises n₁ scan cells denoted 206-1 through 206-n₁. More generally, scan chain 204-k is of length nₖ and therefore comprises a total of nₖ scan cells.

In some embodiments of the invention, the lengths of the scan chains 204 are balanced so that the same amount of time is needed to shift a desired set of scan test patterns into all of the scan chains. It may therefore be assumed without limitation that all of the scan chains 204 are of the same length n, such that n₁=n₂= . . . =nₖ=n.

Circuitry under test 207 in this embodiment comprises a plurality of combinational logic blocks, of which exemplary blocks 208, 210 and 212 are shown. The combinational logic blocks are illustratively arranged between primary inputs 214 and primary outputs 216 and separated from one another by the scan chains 204.

Combinational logic blocks such as 208, 210 and 212 may be viewed as examples of what are more generally referred to herein as “additional circuitry” that is subject to testing utilizing scan test circuitry in embodiments of the invention. By way of example, such internal circuitry blocks of integrated circuit 104 may represent portions of different integrated circuit cores, such as respective read channel and additional cores of a system-on-chip (SOC) integrated circuit in a hard disk drive (HDD) controller application, designed for reading and writing data from one or more magnetic storage disks of an HDD. In other embodiments, the circuit blocks subject to testing by the scan chains may comprise other types of functional logic circuitry, in any combination, and the term “additional circuitry” is intended to be broadly construed so as to cover any such arrangements of logic circuitry.

The decompressor 200 of the scan test circuitry 106 receives compressed scan data from the tester 102 and decompresses that scan data to generate scan test input data that is shifted into the scan chains 204 when such chains are configured as respective serial shift registers in the scan shift phase of the scan shift mode of operation. The compressor 202 of the scan test circuitry 106 receives scan test output data shifted out of the scan chains 204, also when such chains are configured as respective serial shift registers in the scan shift phase of the scan shift mode of operation, and compresses that scan test output data for delivery back to the tester 102.

Compressed scan input data is applied by tester 102 to M scan inputs of decompressor 200, and compressed scan output data is provided from compressor 202 back to tester 102 via M scan outputs. As noted previously, the K scan chains 204 are arranged in parallel between respective outputs of the decompressor 200 and respective inputs of the compressor 202 as shown. Each of the individual scan chains 204 is configurable to operate as a serial shift register in the scan shift phase of a scan test mode of operation of the integrated circuit 104 and also to capture functional data from combinational logic elements. The capture of functional data may be said to occur in a capture phase of the scan test mode. Again, other arrangements of operating modes and phases may be used in other embodiments.

The number K of scan chains 204 is generally much larger than the number M of decompressor inputs or compressor outputs. The ratio of K to M provides a measure of the degree of scan test pattern compression provided in the scan test circuitry 106. It should be noted, however, that the number of compressor outputs need not be the same as the number of decompressor inputs. For example, there may be M decompressor inputs and P compressor outputs, where M # P but both M and P are much smaller than K.

The scan inputs of the decompressor 200 may be viewed as corresponding to respective ones of what are more generally referred to herein as “scan channels” of the integrated circuit 104.

Additional details regarding the operation of scan compression elements such as decompressor 200 and compressor 202 may be found in the above-cited U.S. Pat. No. 7,831,876, entitled “Testing a Circuit with Compressed Scan Subsets.” Again, scan compression elements such as decompressor 200 and compressor 202 may not be present in other embodiments of the invention. In an embodiment of the invention without scan compression, where the decompressor 200 and compressor 202 are eliminated, the scan channels may simply correspond to respective ones of the scan chains 204.

A given test pattern applied to the scan chains 204 in the present embodiment may be viewed as a scan vector, where a scan vector comprises a shift-in phase in which scan test input data is shifted into all of the scan chains 204, followed by a capture phase in which functional data is captured, followed by a shift-out phase in which scan test output data is shifted out from all of the scan chains 204. The scan vectors for different test patterns may overlap with one another, in that as input data is shifted in for a given test pattern, captured data for a previous pattern may be shifted out. The shift-in and shift-out phases may be individually or collectively referred to herein as one or more scan shift phases of the scan vector or associated test pattern. As noted above, such scan shift phases may be viewed as being part of a scan test mode of operation of the integrated circuit 104.

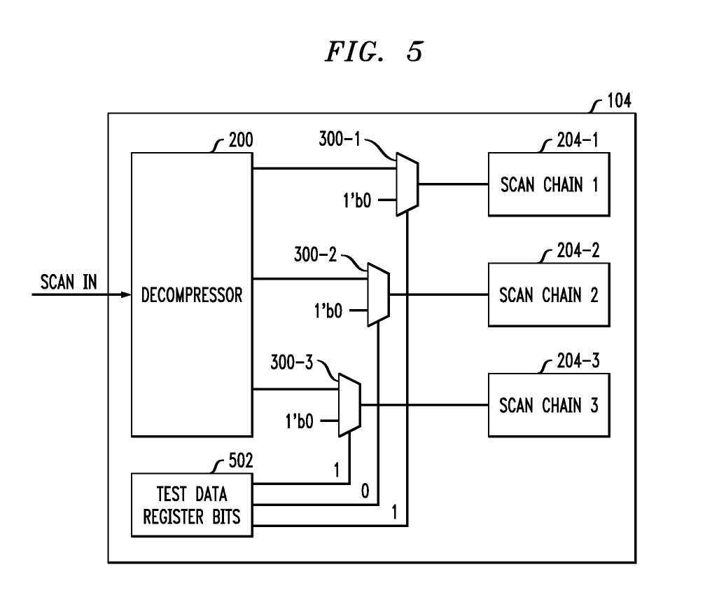

In the FIG. 2 embodiment, the integrated circuit 104 comprises control circuitry 220. As will be described in greater detail below in conjunction with FIGS. 3 through 6, the control circuitry 220 comprises first switching elements configured to control selective application of respective scan input signals to respective scan inputs of respective ones of the scan chains 204 and second switching elements configured to control selective application of a shift enable signal to shift enable inputs of the respective ones of the scan chains 204. More particularly, in the embodiments of FIGS. 3 through 6, each of the scan chains 204 has associated therewith both a first switching element and a second switching element, with the switching elements being implemented as respective two-to-one multiplexers.

The control circuitry 220 as illustrated in FIG. 2 comprises one or more test data registers 222. At least a given one of the test data registers 222 is configured to store separate test data register bits for the respective scan chains 204. A given one of the test data register bits controls switching states of both the first switching element and the second switching element associated with the corresponding scan chain 204. Accordingly, by manipulation of the test data register bits via tester 102, a selected subset of the scan chains 204 can have predetermined signal values at designated logic levels applied to their respective scan inputs and shift enable inputs in place of the scan input signals and shift enable signal, so as to thereby support a compression debug mode of operation. A wide variety of other types of debug modes can be supported in other embodiments.

The test data registers 222 may be implemented using any type of memory or other storage elements in any desired configuration, and the term is therefore intended to be broadly construed herein.

The control circuitry 220 may additionally comprise other types of circuitry, such as, for example, a clock distribution network that is configured to provide a plurality of clock signals to respective portions of the integrated circuit 104. A given “portion” of an integrated circuit as that term is used herein is intended to be broadly construed, and should be understood to encompass any circuit element or other identifiable component, or set of such elements or other components, that are implemented within the integrated circuit. The clock distribution network in the present embodiment may be configured to provide clock signals to the scan chains 204 and to the combinational logic blocks 208, 210 and 212.

The control circuitry 220 will now be described in greater detail with reference to FIGS. 3 through 6. FIGS. 3 and 4 illustrate the operation of the above-noted first and second switching elements, respectively, for a given scan chain 204-1. FIG. 5 illustrates the manner in which multiple instances of the first switching elements are associated with respective ones of a plurality of scan chains 204-1, 204-2 and 204-3. Finally, FIG. 6 includes the FIG. 5 circuitry but further illustrates the manner in which multiple instances of the second switching elements are associated with the respective scan chains 204-1, 204-2 and 204-3.

Referring initially to FIG. 3, a portion of the integrated circuit 104 is shown as comprising decompressor 200 and scan chain 204-1. The decompressor 200 has an input signal line denoted SCAN IN over which it receives a compressed signal from the tester 102. The decompressor 200 decompresses the received compressed test signal in order to generate multiple scan input signals for application to respective scan inputs of respective ones of the scan chains 204. In this figure, the above-noted first switching element comprises a first multiplexer 300 coupled between an output of the decompressor 200 and a scan input of the scan chain 204-1. Although not illustrated, other first multiplexers are similarly coupled between respective other outputs of the decompressor 200 and respective scan inputs of the other scan chains 204-2 through 204-K.

The first multiplexer 300 more particularly comprises a two-input multiplexer having a first input coupled to the output of the decompressor 200, a second input coupled to a source of a first predetermined signal value at a first logic level, an output coupled to the scan input of the corresponding scan chain 204-1, and a select signal input controlled by a corresponding test data register bit 302. The test data register bit 302 is assumed to be part of one of the test data registers 222.

In this embodiment, the first predetermined signal value at the first logic level is a logic low signal denoted 1′b0. This arrangement may be implemented by coupling the corresponding multiplexer input signal line to a logic low signal source, such as ground potential. The multiplexer 300 select signal input is driven by the test data register bit 302, such that when the test data register bit 302 is at a logic high level, a constant “0” value is applied to the scan input of the scan chain 204-1, and when the test data register bit 302 is at a logic low level, the output of the decompressor 200 is applied to the scan input of the scan chain 204-1.

Turning now to FIG. 4, the control circuitry 220 further comprises a second switching element illustratively implemented as a second multiplexer 400 coupled between a shift enable signal line SE of the scan test circuitry and a corresponding shift enable input of the scan chain 204-1. It is assumed that all of the scan cells 206 of the scan chain 204-1 have shift enable inputs that are tied together to form a single shift enable input for the scan chain as illustrated in the figure, with the single shift enable input of the scan chain being driven by the output of the second multiplexer 400. The shift enable inputs of the scan cells of scan chain 204-1 are also denoted in the figure as SE inputs. Although not illustrated, other second multiplexers are similarly coupled between the SE signal line and respective shift enable inputs of the other scan chains 204-2 through 204-K.

The second multiplexer 400 more particularly comprises a two-input multiplexer having a first input coupled to the SE signal line, a second input coupled to a source of a second predetermined signal value at a second logic level, an output coupled to the shift enable input of the corresponding scan chain 204-1, and a select signal input controlled by a corresponding test data register bit 402. The test data register bit 402 is also assumed to be part of one of the test data registers 222, and may in fact be the same test data register bit 302 that is used to control the first multiplexer 300 in FIG. 3. An arrangement of this type, in which the same test data register bit controls both the first and second multiplexers associated with a given one of the scan chains 204, will be described in conjunction with FIG. 6. These test data register bits may be viewed as examples of what are also referred to herein as “scan chain specific control signals.”

In this embodiment, the second predetermined signal value at the second logic level is a logic high signal denoted 1′b1. This arrangement may be implemented by coupling the corresponding multiplexer input signal line to a logic high signal source, such as an upper supply voltage potential. The multiplexer 400 select signal input is driven by the test data register bit 402, such that when the test data register bit 402 is at a logic high level, a constant “1” value is applied to the shift enable input of the scan chain 204-1, and when the test data register bit 402 is at a logic low level, the shift enable signal on the SE signal line is applied to the shift enable input of the scan chain 204-1.

Although the first and second predetermined signal values applied to the lower inputs of respective multiplexers 300 and 400 have opposite logic levels in FIGS. 3 and 4, other signaling arrangements can be used in other embodiments. Also, the term “switching element” as used herein is intended to be broadly construed, so as to encompass switching circuitry other than the multiplexers used in these embodiments.

The control circuitry 220 comprising instances of first multiplexer 300 and second multiplexer 400 for each of the scan chains 204 allows a constant value from multiplexer 300 to be shifted into one or more of the scan chains 204 while one or more other scan chains 204 receive their respective scan inputs from the decompressor 200. This considerably facilitates debug of compression faults.

For example, in one possible compression debug mode of operation, a first subset of the first and second switching elements of the control circuitry 220 are configured such that scan input signals from the decompressor 200 are applied to the scan inputs of the corresponding scan chains 204 and the shift enable signal is applied to the shift enable inputs of the corresponding scan chains 204, and a second subset of the first and second switching elements of the control circuitry 220 are configured such that the first predetermined signal value at the first logic level is applied to the scan inputs of the corresponding scan chains 204 and the second predetermined signal value at the second logic level is applied to the shift enable inputs of the corresponding scan chains 204.

Such compression debug modes of operation may also be referred to herein as diagnostic scan testing modes of operation. As noted above, embodiments of the invention can be configured to support a wide variety of different types or diagnostic or debug modes of operation.

In a normal scan testing mode of operation, the first switching elements are configured to apply the scan input signals to the scan inputs of the respective scan chains 204 and the second switching elements are configured to apply the shift enable signal to the shift enable inputs of the respective scan chains 204.

FIG. 5 illustrates an embodiment in which multiple instances of the first multiplexer 300 of FIG. 3 are associated with respective ones of multiple scan chains. In this figure, three scan chains 204-1, 204-2 and 204-3 are illustrated, also referred to as Scan Chain 1, Scan Chain 2 and Scan Chain 3, respectively. Separate first multiplexers 300-1, 300-2 and 300-3 are coupled between respective outputs of the decompressor 200 and respective scan inputs of the respective scan chains 204-1, 204-2 and 204-3, with each such first multiplexer being configured substantially as previously described in conjunction with FIG. 3. The select signal inputs of the respective multiplexers 300-1, 300-2 and 300-3 are driven by respective ones of a plurality of test data register bits 502.

FIG. 6 shows the control circuitry 220 including the first multiplexers 300-1, 300-2 and 300-3 as previously described in conjunction with FIG. 5, with the addition of multiple instances of the second multiplexer 400. Separate second multiplexers 400-1, 400-2 and 400-3 are coupled between the SE signal line and respective shift enable inputs of the respective scan chains 204-1, 204-2 and 204-3, with each such second multiplexer being configured substantially as previously described in conjunction with FIG. 4. The select signal inputs of the respective second multiplexers 400-1, 400-2 and 400-3 are driven by respective ones of the test data register bits 502, and more particularly by the same respective ones of the test data register bits 502 that drive the select signal inputs of the respective first multiplexers 300-1, 300-2 and 300-3.

The test data register bits 502 in FIGS. 5 and 6 are illustrated as being set to “1”, “0” and “1” for the respective multiplexers 300-1, 300-2 and 300-3. Such an arrangement is useful, for example, to allow compression debugging of Scan Chain 2 by shifting constant “0” values into Scan Chain 1 and Scan Chain 3 while driving Scan Chain 2 with the output of the decompressor 200. This makes the contents of Scan Chain 2 readily observable in the output of the compressor 202, thereby facilitating detection of compression faults associated with Scan Chain 2. Scan Chains 1 and 3 can be similarly tested by appropriate manipulation of the test data register bits 502 via the tester 102.

More generally, of the K scan chains 204-1 through 204-K in the FIG. 2 embodiment, up to K−1 of the scan chains can be configured via control circuitry 220 such that constant values are shifted into those chains, while the remaining scan chain or chains are driven by respective outputs of the decompressor 200. Thus, debugging can be performed on a single scan chain or a group of two or more scan chains.

Such an arrangement considerably facilitates the debugging of compression faults associated with particular ones of the scan chains 204. Diagnostic resolution is considerably improved, permitting straightforward identification of one or more scan cells that have contributed to a given test pattern failure. For example, contents of individual scan chains 204 can be readily isolated and observed at the output of the compressor 202.

Also, switching between compression debug or other debug modes and a normal scan testing mode can be accomplished very easily by appropriate manipulation of the test data register bits or other scan chain specific control signals.

It is to be appreciated that the particular circuitry arrangements shown in FIGS. 1-6 are presented by way of illustrative example only, and numerous alternative arrangements of scan test circuitry, scan chains, control circuitry and switching elements may be used to implement the described functionality. This functionality can be implemented in one or more of the embodiments without any significant negative impact on integrated circuit area requirements or functional timing requirements.

The presence of control circuitry elements of the type described above within integrated circuit 104 may be made apparent to a test pattern generator or other test generation tool so that the tool can take the associated functionality into account in generating test patterns. In order to accomplish this, one or more input files describing the operation of this circuitry may be provided to the test generation tool.

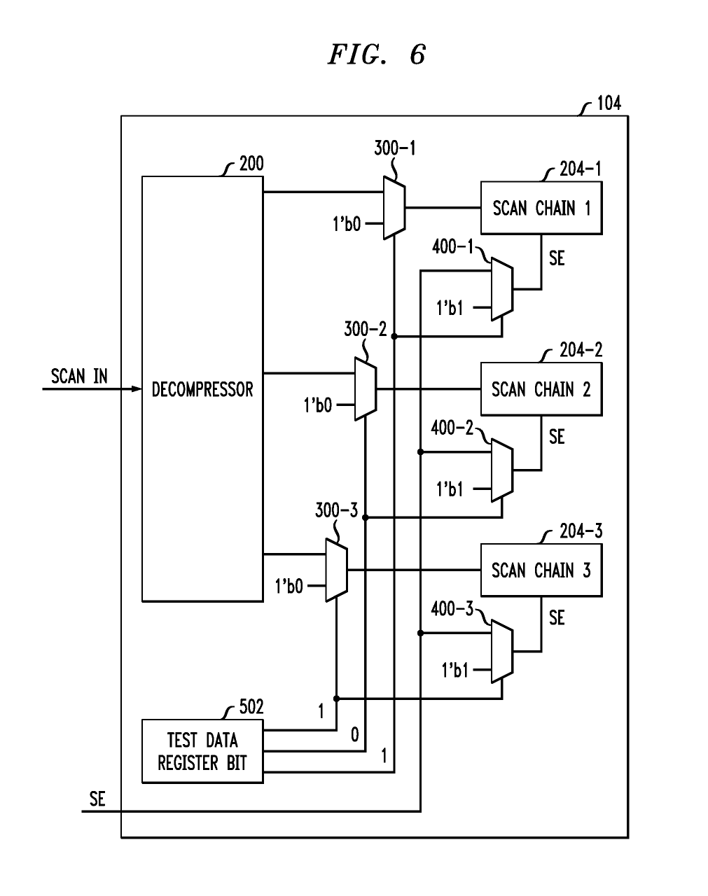

The tester 102 in the testing system 100 of FIG. 1 need not take any particular form, and various conventional testing system arrangements can be modified in a straightforward manner to support the debug functionality disclosed herein. One possible example is shown in FIG. 7, in which a tester 702 comprises a load board 704 in which an integrated circuit 705 to be subject to scan testing using the techniques disclosed herein is installed in a central portion 706 of the load board 704. The tester 702 also comprises processor and memory elements 707 and 708 for executing stored program code. In the present embodiment, processor 707 is shown as implementing a test pattern generator 712, which may be implemented as an ATPG. Associated scan data 710 is stored in memory 708. Numerous alternative testers may be used to perform scan testing of an integrated circuit as disclosed herein. Also, as indicated previously, in alternative embodiments at least portions of the tester 702 may be incorporated into the integrated circuit itself, as in BIST arrangement.

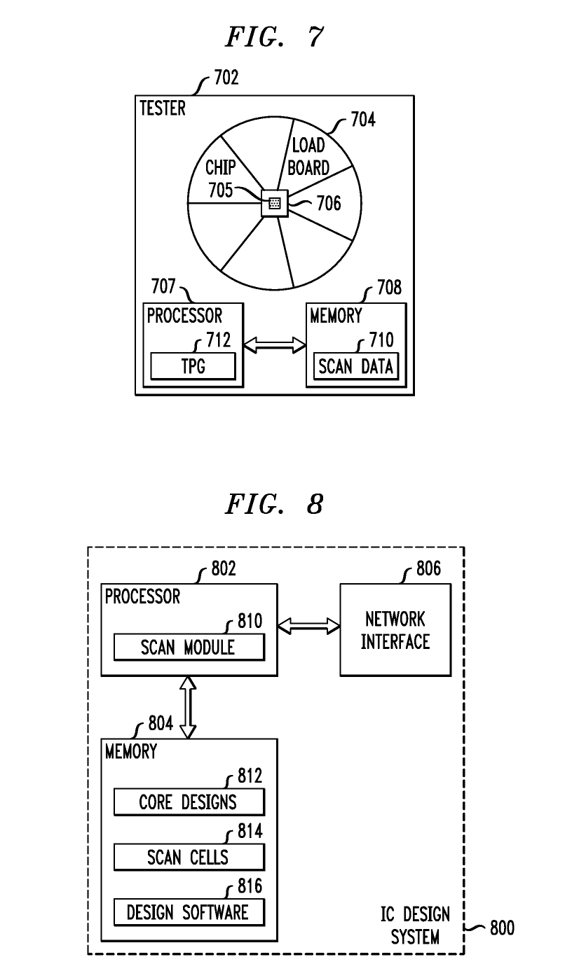

The insertion of scan chains 204 and associated control circuitry 220 of a given integrated circuit design may be performed in a processing system 800 of the type shown in FIG. 8. Such a processing system in this embodiment more particularly comprises a design system configured for use in designing integrated circuits such as integrated circuit 104 to include scan chains 204 and associated control circuitry 220.

The system 800 comprises a processor 802 coupled to a memory 804. Also coupled to the processor 802 is a network interface 806 for permitting the processing system to communicate with other systems and devices over one or more networks. The network interface 806 may therefore comprise one or more transceivers. The processor 802 implements a scan module 810 for supplementing core designs 812 with scan cells 814 and associated control circuitry elements in the manner disclosed herein, in conjunction with utilization of integrated circuit design software 816.

By way of example, the scan chain circuitry 106 comprising scan chains 204 and associated control circuitry 220 may be generated in system 800 using an RTL description and then synthesized to gate level using a specified technology library. More particularly, the multiplexers 300 and 400 can be inserted into an integrated circuit design following normal scan insertion, using a design compiler and automated script to insert the multiplexers in the scan input and shift enable paths for each scan chain.

A test generation model may then be created for generating test patterns using a test generation tool. Control files or other types of input files may be used to provide the test generation tool with information such as the particular scan chains that are associated with particular multiplexers and test data register bits in a given embodiment. Once the corresponding rules are in place, a rule checker may be run so that the test generation tool has visibility of the scan chains taking into account the operation of the associated control circuitry 220. Test patterns may then be generated for the scan chain circuitry.

Elements such as 810, 812, 814 and 816 are implemented at least in part in the form of software stored in memory 804 and processed by processor 802. For example, the memory 804 may store program code that is executed by the processor 802 to implement particular scan chain and debug control functionality of module 810 within an overall integrated circuit design process. The memory 804 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 802 may comprise a microprocessor, CPU, ASIC, FPGA or other type of processing device, as well as portions or combinations of such devices. The memory 708 of FIG. 7 may be viewed as another illustrative example of a computer program product as the latter term is used herein.

As indicated above, embodiments of the invention may be implemented in the form of integrated circuits. In a given such integrated circuit implementation, identical die are typically formed in a repeated pattern on a surface of a semiconductor wafer. Each die includes scan test circuitry having control circuitry with switching elements as disclosed herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

It should again be emphasized that the embodiments of the invention as described herein are intended to be illustrative only. For example, other embodiments of the invention can be implemented using a wide variety of other types of integrated circuits, scan test circuitry and additional circuitry subject to testing, with different types and arrangements of scan cells, scan chains and associated control circuitry, as well as different types and arrangements of switching elements and control signaling, than those included in the embodiments described herein. These and numerous other alternative embodiments within the scope of the following claims will be readily apparent to those skilled in the art.

What is claimed is:

1. An integrated circuit comprising:
scan test circuitry comprising a plurality of scan chains each having a plurality of scan cells; and
additional circuitry subject to testing utilizing the scan test circuitry;
the scan test circuitry further comprising:
control circuitry comprising first switching elements configured to control selective application of respective scan input signals to respective scan inputs of respective ones of the plurality of scan chains and second switching elements configured to control selective application of a shift enable signal to shift enable inputs of the respective ones of the plurality of scan chains.

2. The integrated circuit of claim 1 wherein the control circuitry further comprises a test data register configured to store separate test data register bits for the respective scan chains.

3. The integrated circuit of claim 1 wherein a given one of the test data register bits controls switching states of both the first switching element and the second switching element associated with the corresponding scan chain, such that by manipulation of the test data register bits a selected subset of the scan chains can have predetermined signal values at designated logic levels applied to their respective scan inputs and shift enable inputs in place of the scan input signals and shift enable signal, so as to thereby support a debug mode of operation.

4. The integrated circuit of claim 1 wherein the scan test circuitry further comprises:
a decompressor configured to generate the scan input signals; and
a compressor configured to process scan output signals provided by the respective scan chains.

5. The integrated circuit of claim 4 wherein the first switching elements comprise respective first multiplexers each coupled between an output of the decompressor and a corresponding one of the scan inputs of the respective scan chains.

6. The integrated circuit of claim 5 wherein a given one of the first multiplexers comprises a two-input multiplexer having a first input coupled to the output of the decompressor, a second input coupled to a source of a first predetermined signal value at a first logic level, an output coupled to the scan input of the corresponding scan chain, and a select signal input controlled by a corresponding test data register bit.

7. The integrated circuit of claim 1 wherein the second switching elements comprise respective second multiplexers each coupled between a shift enable signal line of the scan test circuitry and a corresponding one of the shift enable inputs of the respective scan chains.

8. The integrated circuit of claim 7 wherein a given one of the second multiplexers comprises a two-input multiplexer having a first input coupled to the shift enable signal line, a second input coupled to a source of a second predetermined signal value at a second logic level, an output coupled to the shift enable input of the corresponding scan chain, and a select signal input controlled by a corresponding test data register bit.

9. The integrated circuit of claim 1 wherein the first and second switching elements associated with a given one of the scan chains are controlled by a scan chain specific control signal, wherein the first switching element applies a selected one of the scan input signal and a first predetermined signal value to the scan input of the corresponding scan chain responsive to the scan chain specific control signal and the second switching element applies a selected one of the shift enable signal and a second predetermined signal value to the shift enable input of the corresponding scan chain responsive to the scan chain specific control signal.

10. The integrated circuit of claim 9 wherein the scan chain specific control signal comprises at least one test data register bit.

11. The integrated circuit of claim 9 wherein as part of a scan test mode of operation the first switching elements are configured to apply the scan input signals to the scan inputs of the respective scan chains and the second switching elements are configured to apply the shift enable signal to the shift enable inputs of the respective scan chains.

12. The integrated circuit of claim 9 wherein as part of a debug mode of operation a first subset of the first and second switching elements are configured such that the scan input signals are applied to the scan inputs of the corresponding scan chains and the shift enable signal is applied to the shift enable inputs of the corresponding scan chains, and a second subset of the first and second switching elements are configured such that a first predetermined signal value at a first logic level is applied to the scan inputs of the corresponding scan chains and a second predetermined signal value at a second logic level is applied to the shift enable inputs of the corresponding scan chains.

13. A processing device comprising the integrated circuit of claim 1.

14. A method comprising:
controlling selective application of scan input signals to respective scan inputs of respective scan chains of an integrated circuit; and
controlling selective application of a shift enable signal to shift enable inputs of the respective ones of the plurality of scan chains.

15. The method of claim 14 wherein controlling selective application of the scan input signals and the shift enable signal comprises:
storing separate test data register bits for the respective scan chains;
wherein a given one of the test data register bits controls the selective application of both the scan input signal and the shift enable signal to the corresponding scan chain;
the test data register bits being stored in a debug mode of operation such that a selected subset of the scan chains have predetermined signal values at designated logic levels applied to their respective scan inputs and shift enable inputs in place of the scan input signals and shift enable signal.

16. The method of claim 14 wherein controlling selective application of the scan input signals and the shift enable signal comprises for each of the scan chains:
selecting between application of the scan input signal and a first predetermined signal value to the scan input of the scan chain responsive to a scan chain specific control signal; and
selecting between application of the shift enable signal and a second predetermined signal value to the shift enable input of the scan chain responsive to the scan chain specific control signal.

17. The method of claim 16 wherein during a scan test mode of operation the scan input signal and the shift enable signal are applied to the respective scan input and shift enable input of the scan chain.

18. The method of claim 16 wherein during a debug mode of operation a first subset of the scan chains have the corresponding scan input signals applied to their scan inputs and have the shift enable signal applied to their shift enable inputs, and a second subset of the scan chains have a first predetermined signal value at a first logic level applied to their scan inputs and a second predetermined signal value at a second logic level applied to their shift enable inputs.

19. A computer-readable storage medium having computer program code embodied therein, wherein the computer program code when executed in a testing system causes the testing system to perform the method of claim 14.

20. A processing system comprising:
a processor; and
a memory coupled to the processor and configured to store information characterizing an integrated circuit design;
wherein the processing system is configured to provide scan test circuitry within the integrated circuit design, the scan test circuitry comprising a plurality of scan chains each having a plurality of scan cells;
the scan test circuitry further comprising:
control circuitry comprising first switching elements configured to control selective application of respective scan input signals to respective scan inputs of respective ones of the plurality of scan chains and second switching elements configured to control selective application of respective shift enable signals to respective shift enable inputs of the respective ones of the plurality of scan chains.
